(19) United States
(12) Patent Application Publication
(10) Pub. No.: US 2010/0035421 A1
(43) Pub. Date: Feb. 11, 2010

(54) SEMICONDUCTOR WELL IMPLANTED THROUGH PARTIALLY BLOCKING MATERIAL PATTERN

(75) Inventors: Marie Denison, Plano, TX (US); Shanjen Pan, Allen, TX (US)

Correspondence Address: TEXAS INSTRUMENTS INCORPORATED, P O BOX 655474, M/S 3999, DALLAS, TX, 75265, US

(73) Assignee: TEXAS INSTRUMENTS INCORPORATED, Dallas, TX (US)

(21) Appl. No.: 12/536,778

(22) Filed: Aug. 6, 2009

Related U.S. Application Data
(60) Provisional application No. 61/086,701, filed on Aug. 6, 2008.

(51) Int. Cl. H01L 21/265

(52) U.S. Cl. 438/514; 257/E21.334

(57) ABSTRACT

A method for forming a partially blocking layer for an ion implantation process, which may be varied across the IC to form regions with different dopant concentrations, and regions with varying dopant concentrations in each contiguously implanted region, is disclosed. One or more temporary and/or permanent layers may form the partially blocking layer, including a combination of different materials such as polysilicon, silicon dioxide, silicon nitride, and photoresist. The partially blocking layer may be a uniform continuous sheet which transmits a uniform fraction of dopants, or a reticulated screen which transmits dopants through multiple open areas. Several partially blocking layers, each absorbing a different fraction of implanted dopants, may be formed on an IC to produce instances of a component with different performance parameters such as operation voltage, sheet resistance or gain.

### FIELD OF THE INVENTION

This invention relates to the field of integrated circuits. More particularly, this invention relates to methods to improve ion implantation processes used in fabrication of integrated circuits.

### BACKGROUND OF THE INVENTION

Ion implantation is a widely used method of providing dopants during fabrication of integrated circuits (ICs). Typical ion implantation processes which implant dopants into selected areas of an IC require a masking layer to block dopants from regions of the IC where the dopants are not needed. Formation of the masking layer typically involves a photolithographic process, which adds cost and complexity to the IC fabrication process sequence. Forming regions with different dopant concentrations typically requires multiple photolithographic operations to generate a separate masking layer for each dopant concentration.

### SUMMARY OF THE INVENTION

This Summary is provided to comply with 37 C.F.R. §1.73, requiring a summary of the invention briefly indicating the nature and substance of the invention. It is submitted with the understanding that it will not be used to interpret or limit the scope or meaning of the claims.

The instant invention provides a method for forming a partially blocking layer for an ion implantation process in one photolithographic operation, which may be varied across the IC to form regions with different dopant concentration profiles, and regions with varying dopant concentration profiles in each contiguously implanted region. The inventive method uses one or more temporary and/or permanent layers, including a combination of different materials, to form the partially blocking layer, to change an average implanted depth and concentration of dopants compared to a region without a partially blocking layer. Several partially blocking layers, each absorbing a different fraction of implanted dopants, may be formed on an IC to produce instances of a component with different performance parameters such as operation voltage, sheet resistance or gain.

### DESCRIPTION OF THE VIEWS OF THE DRAWING

FIG. 1A through FIG. 1K are cross-sections of different regions of an IC with partially blocking layers formed according to the instant invention.

FIG. 2A through FIG. 2C illustrate a use of multiple partially blocking layers to tailor more than one set of ion implanted dopants.

FIG. 3A through FIG. 3E are top views of various configurations of partially blocking layers.

FIG. 4A through FIG. 4D depict two ICs fabricated on different substrates with two different angled ion implantation processes through identical partially blocking layers.

FIG. 5A and FIG. 5B illustrate a use of a reticulated partially blocking layer with areas of different transmission fractions to obtain a contiguous implanted region with a varying concentration of dopant atoms.

FIG. 6A and FIG. 6B are cross-sections of an IC with two embodiments of the instant invention to modify base regions of bipolar transistors.

FIG. 7A and FIG. 7B are cross-sections of an IC with two embodiments of the instant invention to modify drain regions of DEMOS transistors.

FIG. 8 is a cross-section of an IC with two implanted resistors formed according embodiments of the instant invention.

FIG. 9A and FIG. 9B are cross-sections of an IC with two junction field effect transistors (JFETs) formed according embodiments of the instant invention.

FIG. 10A and FIG. 10B are cross-sections of an IC with two lateral insulated gate bipolar transistors (L-IGBTs) formed according to embodiments of the instant invention.

### DETAILED DESCRIPTION

The present invention is described with reference to the attached figures, wherein like reference numerals are used throughout the figures to designate similar or equivalent elements. The figures are not drawn to scale and they are provided merely to illustrate the invention. Several aspects of the invention are described below with reference to example applications for illustration. It should be understood that numerous specific details, relationships, and methods are set forth to provide a full understanding of the invention. One skilled in the relevant art, however, will readily recognize that the invention can be practiced without one or more of the specific details or with other methods. In other instances, well-known structures or operations are not shown in detail to avoid obscuring the invention. The present invention is not limited by the illustrated ordering of acts or events, as some acts may occur in different orders and/or concurrently with other acts or events. Furthermore, not all illustrated acts or events are required to implement a methodology in accordance with the present invention.

A fabrication process sequence for an integrated circuit (IC) may be simplified according the instant invention, which provides a method for forming a partially blocking layer for an ion implantation process in one photolithographic operation, which may be varied across the IC to form regions with different dopant concentrations, and regions with varying dopant concentrations in each contiguously implanted region. The inventive method uses one or more temporary and/or permanent layers, including a combination of different materials, to form the partially blocking layer, to change an average implanted depth and concentration of dopants compared to a region without a partially blocking layer.

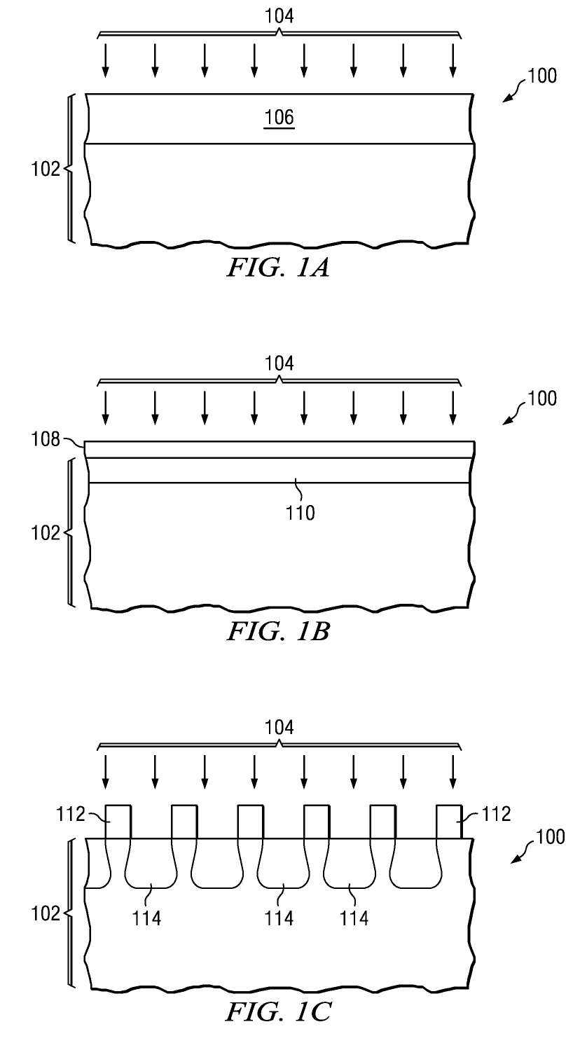

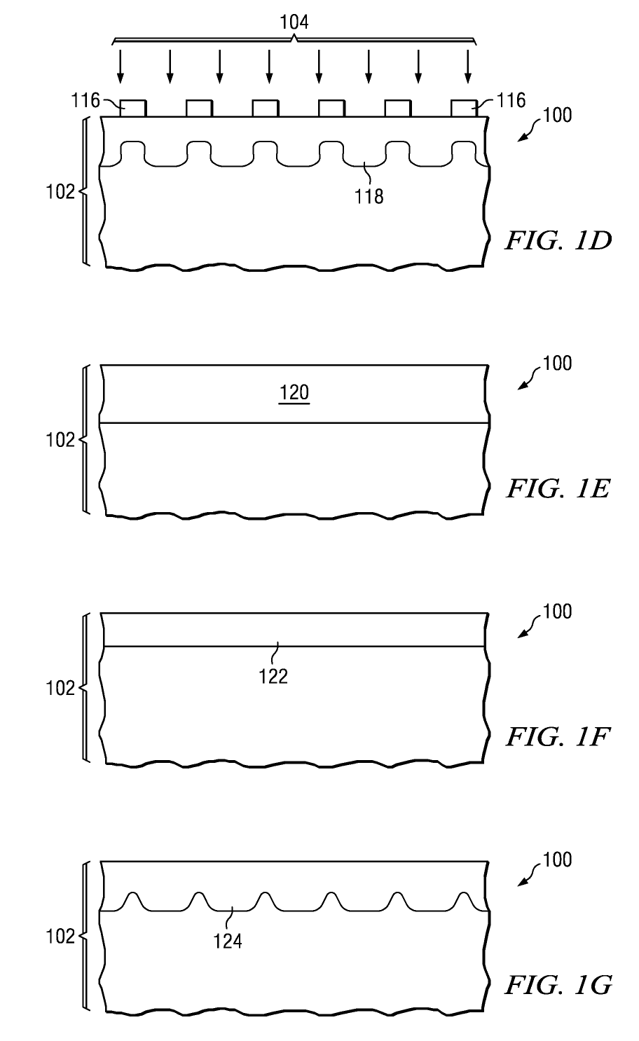

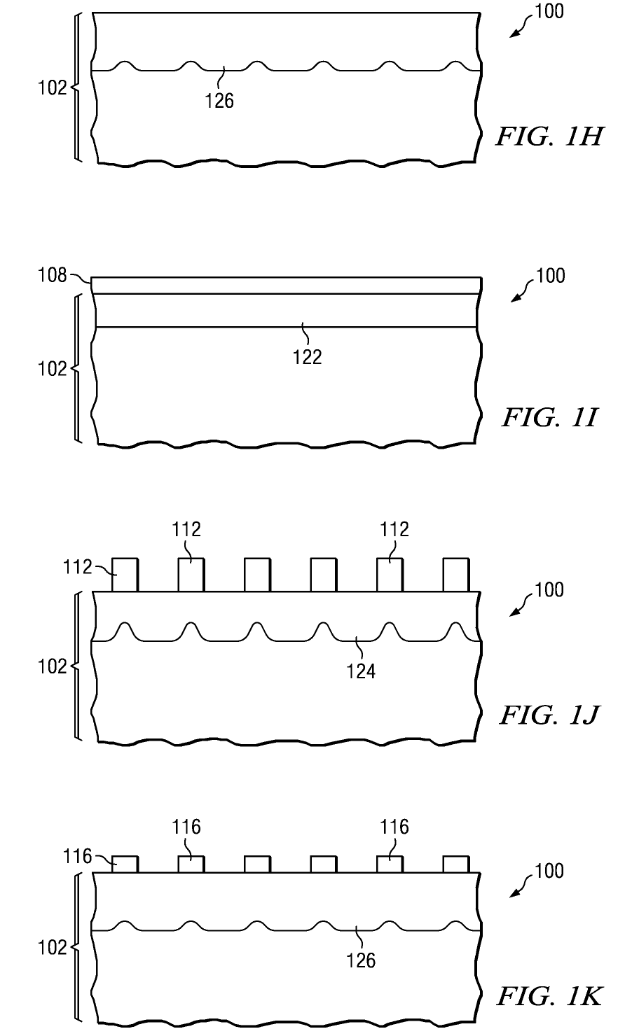

FIG. 1A through FIG. 1H are cross-sections of different regions of an IC with partially blocking layers formed according to the instant invention, during an ion implantation process and after an anneal of implanted regions. FIG. 1A depicts a region of the IC with no partially blocking layer, for comparison purposes to regions with partially blocking layers. The IC (100) includes a substrate (102), typically single crystal silicon, but possibly another semiconductor material. It is common to form a thin layer of sacrificial material, typically silicon dioxide, on a top surface of the substrate (102), commonly known as a pad oxide or sacrificial oxide, to protect the top surface of the substrate during processing. A thickness of the pad oxide is typically 2 to 20 nanometers, and much less than a depth of any dopants which will be implanted into the substrate (102) while the pad oxide is in place. A pad oxide layer is not shown in FIG. 1A through FIG. 1H for clarity. A first set of dopants (104) is ion implanted into the substrate (102) to form a first implanted region (106), at one or more implantation energies. A depth of the first implanted region is determined primarily by the maximum implantation energy and secondarily by a dose of the first set of dopants (104). The first implanted region (106) may or may not extend to the top surface of the substrate (102), depending on the implantation energies.

FIG. 1B depicts a region of the IC (100) with a solid partially blocking layer (108) formed on the top surface of the substrate (102). The solid partially blocking layer (108) may be composed of photoresist or other organic material deposited by dispensing a liquid containing the photoresist or other organic material on the top surface of the substrate (102), silicon dioxide deposited by known methods of plasma enhanced chemical vapor deposition (PECVD) or decomposition of tetra-ethoxy silane (TEOS) or dispensing methylsilsesquioxane (MSQ) on the top surface of the substrate (102), silicon nitride deposited by known PECVD methods on the top surface of the substrate (102), polycrystalline silicon commonly known as polysilicon deposited by known growth methods on the top surface of the substrate (102), silicon oxynitride deposited by known PECVD methods on the top surface of the substrate (102), or other material compatible with fabrication of the IC (100). A thickness of the solid partially blocking layer (108) is selected so that a portion of the first set of dopants (104), preferably between 25 and 75 percent, is absorbed by the solid partially blocking layer (108), and the remainder go through the solid partially blocking layer (108) and into the substrate (102) to form a second implanted region (110). The second implanted region (110) is formed concurrently with the first implanted region (106). A depth of the second implanted region (110) in the substrate (102) is less than the depth of the first implanted region (106). Similarly, a dopant concentration of the second implanted region (110) in the substrate (102) is less than a dopant concentration of the first implanted region (106).

FIG. 1C depicts a region of the IC (100) with a thick reticulated partially blocking layer (112) formed on the top surface of the substrate (102). The thick reticulated partially blocking layer (112) may be formed of any of the materials recited for use in the solid partially blocking layer (108) discussed in reference to FIG. 1B. A thickness of the thick reticulated partially blocking layer (112) is selected so that dopant atoms from the first set of dopants (104) impacting a top surface of the thick reticulated partially blocking layer (112) are substantially all absorbed by the thick reticulated partially blocking layer (112). Dopant atoms which do not impact a top surface of the thick reticulated partially blocking layer (112) form a third implanted region (114) which may consist of separate implanted areas, depending on a layout of the thick reticulated partially blocking layer (112). The third implanted region (114) is formed concurrently with the first implanted region (106). In a preferred embodiment, a fraction of dopant atoms in the first set of dopants (104) which form the third implanted region (114) is between 5 and 95 percent. A depth of the third implanted region (114) in the substrate (102) is substantially equal to or possibly marginally less than the depth of the first implanted region (106). A dopant concentration of the third implanted region (114) in the substrate (102) is less than the dopant concentration of the first implanted region (106).

FIG. 1D depicts a region of the IC (100) with a thin reticulated partially blocking layer (116) formed on the top surface of the substrate (102). The thin reticulated partially blocking layer (116) may be formed of any of the materials recited for use in the solid partially blocking layer (108) discussed in reference to FIG. 1B. A thickness of the thin reticulated partially blocking layer (116) is selected so that a portion of the dopant atoms from the first set of dopants (104) impacting a top surface of the thin reticulated partially blocking layer (116) are partially absorbed by the thin reticulated partially blocking layer (116), and the remainder go through the thin reticulated partially blocking layer (116) and into the substrate (102) to form part of a fourth implanted region (118). The fourth implanted region (118) is formed concurrently with the first implanted region (106). In a preferred embodiment, between 25 and 75 percent of the dopant atoms impacting the top surface of the thin reticulated partially blocking layer (116) are absorbed by the thin reticulated partially blocking layer (116). Dopant atoms which do not impact a top surface of the thin reticulated partially blocking layer (116) form the remainder of the fourth implanted region (118). In a preferred embodiment, a fraction of dopant atoms in the first set of dopants (104) which form the fourth implanted region (118) is between 5 and 95 percent. A maximum depth of the fourth implanted region (118) in the substrate (102) is substantially equal to or possibly less than the depth of the first implanted region (106). A dopant concentration of the fourth implanted region (118) in the substrate (102) is less than the dopant concentration of the first implanted region (106).

A dose of the first set of dopants (104) may be adjusted to obtain a desired dopant concentration in one or more of the implanted regions (106, 110, 114, 118). Similarly, an implantation energy of the first set of dopants (104) may be adjusted to obtain a desired depth of one or more of the implanted regions (106, 110, 114, 118).

FIG. 1E depicts the region of the IC (100) depicted in FIG. 1A after an anneal operation which repairs damage to a crystal structure of the substrate (102) done by the ion implantation of the first set of dopants, and activates a portion of dopants in the first implanted region (106) to form a first diffused region (120). A depth of the first diffused region (120) is more than the depth of the first implanted region (106) due to diffusion of the dopants in the first implanted region (106) during the anneal operation. The depth of the first diffused region (120) depends on a time and temperature profile of the anneal operation.

FIG. 1F depicts the region of the IC (100) depicted in FIG. 1B after the anneal operation. A portion of dopants in the second implanted region (110) are activated by the anneal operation to form a second diffused region (122). A depth of the second diffused region (122) in the substrate (102) is less than the depth of the first diffused region (120). Similarly, a dopant concentration of the second diffused region (122) in the substrate (102) is less than a dopant concentration of the first diffused region (120). In the embodiment depicted in FIG. 1F, the solid partially blocking layer (108) is removed during a subsequent fabrication stage of the IC (100). In an alternate embodiment, the solid partially blocking layer (108) may remain on the top surface of the substrate (102), as depicted in FIG. 1I.

FIG. 1G depicts the region of the IC (100) depicted in FIG. 1C after the anneal operation. A portion of dopants in the third implanted region (114) are activated by the anneal operation to form a third diffused region (124). A depth of the third diffused region (124) in the substrate (102) is less than the depth of the first diffused region (120).

FIG. 1H depicts the region of the IC (100) depicted in FIG. 1D after the anneal operation. A portion of dopants in the fourth implanted region (118) are activated by the anneal operation to form a fourth diffused region (126). A depth of the fourth diffused region (126) in the substrate (102) is less than the depth of the first diffused region (120). Similarly, a dopant concentration of the fourth diffused region (126) in the substrate (102) is less than a dopant concentration of the first diffused region (120). Spatial variations in the dopant concentration of the fourth diffused region (126) caused by a reticulated configuration of the thin reticulated partially blocking layer (116) are smoothed by the anneal operation. In the embodiment depicted in FIG. 1H, the thin reticulated partially blocking layer (116) is removed during a subsequent fabrication stage of the IC (100). In an alternate embodiment, the thin reticulated partially blocking layer (116) may remain on the top surface of the substrate (102), as depicted in FIG. 1K.

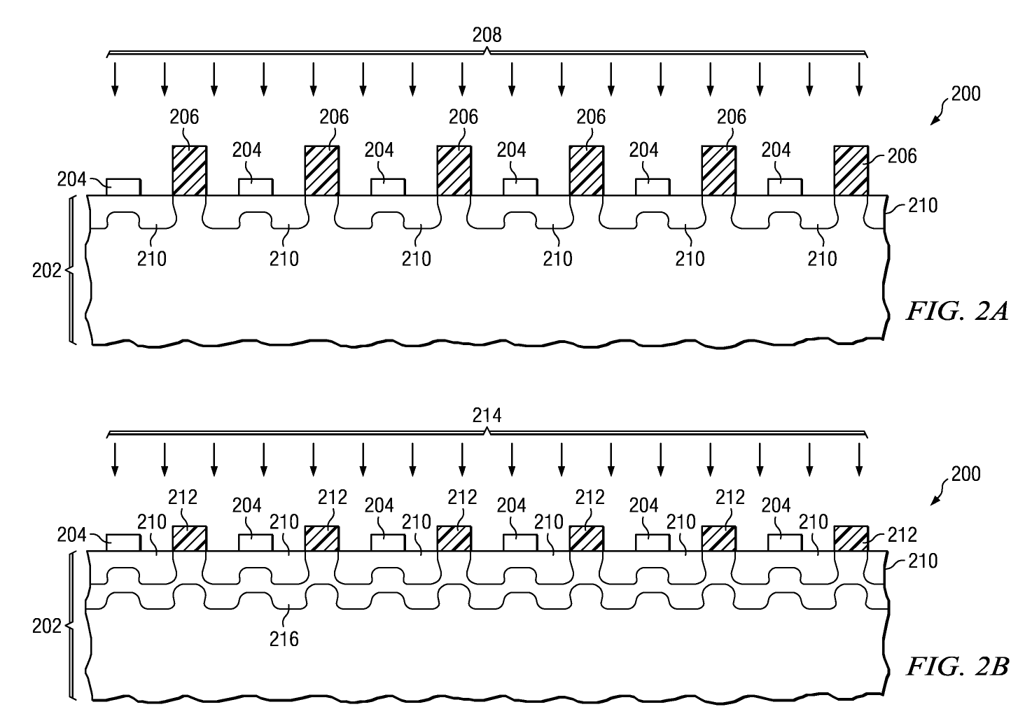

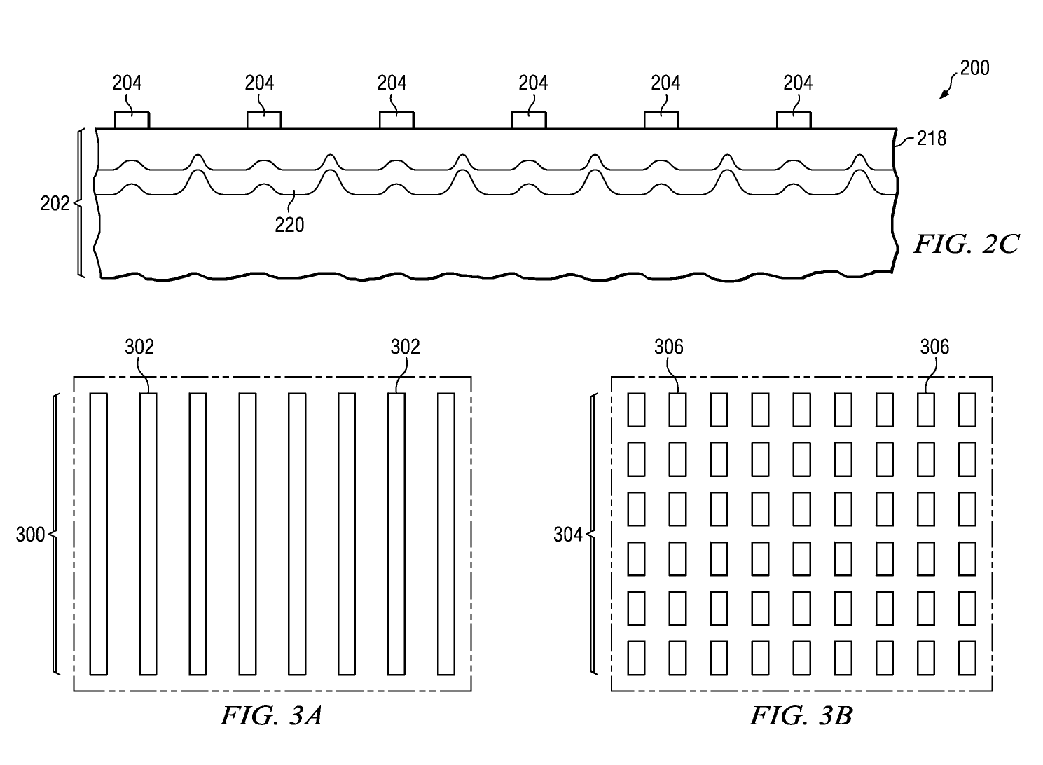

FIG. 2A through FIG. 2C illustrate a use of multiple partially blocking layers to tailor more than one set of ion implanted dopants. A pad oxide layer is not shown in FIG. 2A through FIG. 2C for clarity. Referring to FIG. 2A, an IC (200) includes a substrate (202), typically single crystal silicon, but possibly another semiconductor material. A first blocking layer (204) is formed over a top surface of the substrate (202). In FIG. 2A, the first blocking layer (204) is depicted as a thin reticulated partially blocking layer, but any embodiment of a partially blocking layer, including a solid partially blocking layer or a thick reticulated blocking layer, may be employed. A second partially blocking layer (206) is formed over the top surface of the substrate (202). In FIG. 2A, the second blocking layer (206) is depicted as a thick reticulated partially blocking layer, but any embodiment of a partially blocking layer, including a solid partially blocking layer or a thin reticulated blocking layer, may be employed. A first set of dopants (208) is implanted through the first partially blocking layer (204) and second partially blocking layer (206) into a top region of the substrate (202) to form a first implanted layer (210) in the top region of the substrate (202). The second partially blocking layer (206) may be removed after implanting the first set of dopants (208).

A dose of the first set of dopants (208) may be adjusted to obtain a desired dopant concentration in the first implanted layer (210). Similarly, an implantation energy of the first set of dopants (208) may be adjusted to obtain a desired depth of the first implanted layer (210).

Referring to FIG. 2B, a third partially blocking layer (212) is formed over the top surface of the substrate (202). In FIG. 2B, the third blocking layer (212) is depicted as a thin reticulated partially blocking layer, but any embodiment of a partially blocking layer, including a solid partially blocking layer or a thick reticulated blocking layer, may be employed. A second set of dopants (214) is implanted through the first partially blocking layer (204) and third partially blocking layer (212) into a top region of the substrate (202) to form a second implanted layer (216) in the top region of the substrate (202). The polarity, dose and/or energy of the second set of dopants (214) may be different from the first set of dopants (208). The third partially blocking layer (212) may be removed after implanting the second set of dopants (214).

A dose of the second set of dopants (214) may be adjusted to obtain a desired dopant concentration in the second implanted layer (216). Similarly, an implantation energy of the second set of dopants (214) may be adjusted to obtain a desired depth of the second implanted layer (216).

FIG. 2C depicts the IC (200) after an anneal operation which activates and diffuses a portion of the first set of dopants and a portion of the second set of dopants to form a first annealed region (218) and a second annealed region (220) in the top region of the substrate (202).

Reuse of the first partially blocking layer (204) is advantageous because it reduces fabrication cost and complexity while providing a capability for forming alternate annealed regions in an IC.

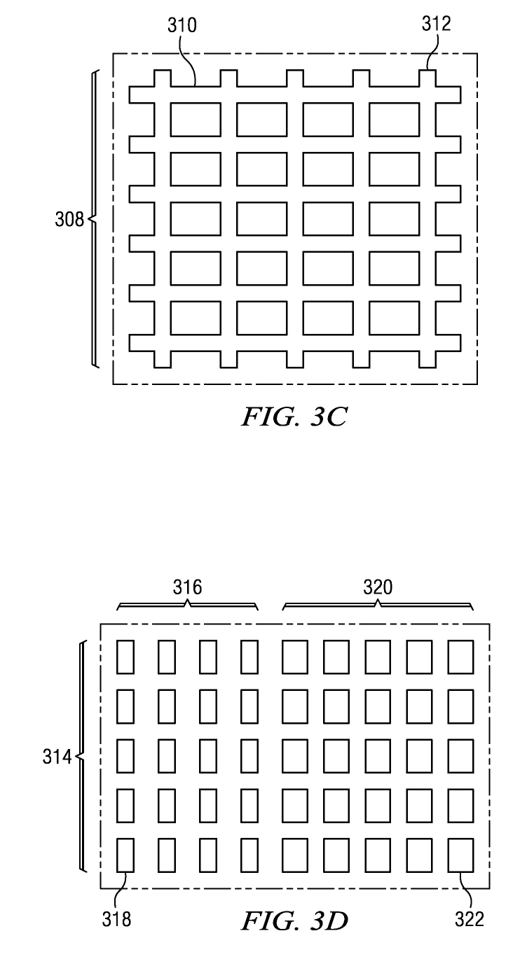

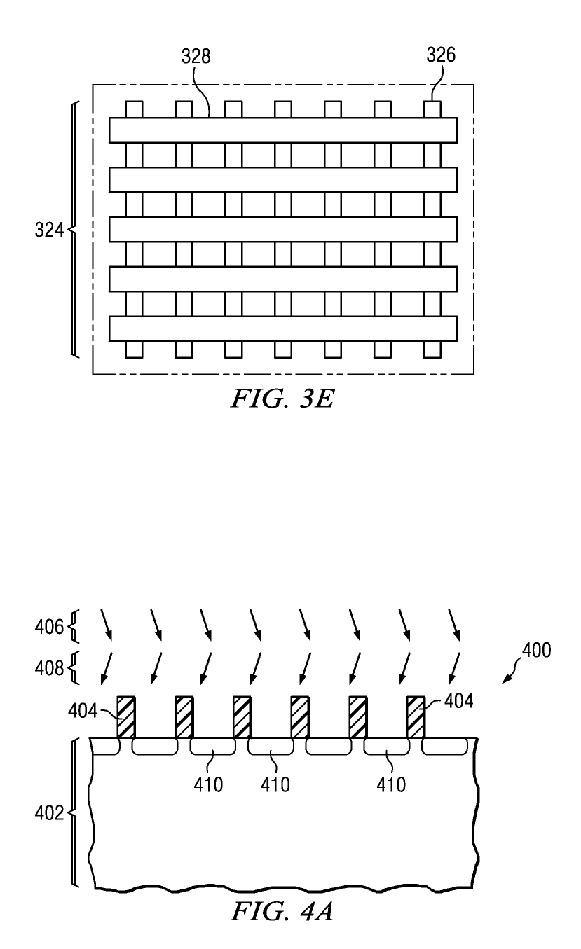

FIG. 3A through FIG. 3E are top views of various configurations of partially blocking layers. FIG. 3A depicts a linear array of long blocking elements (302) which form a first partially blocking layer (300). The blocking elements (302) may form a thick partially blocking layer or a thin partially blocking layer, as described in reference to FIG. 1C and FIG. 1D.

FIG. 3B depicts a rectangular array of short blocking elements (306) which form a second partially blocking layer (304). The blocking elements (306) may form a thick partially blocking layer or a thin partially blocking layer, as described in reference to FIG. 1C and FIG. 1D.

FIG. 3C depicts a rectangular array of horizontal long blocking elements (310) and vertical long blocking elements (312) which form a third partially blocking layer (308). The horizontal blocking elements (310) and vertical blocking elements (312) and may form a thick partially blocking layer or a thin partially blocking layer, as described in reference to FIG. 1C and FIG. 1D.

FIG. 3D depicts a fourth partially blocking layer (314) which includes a first rectangular array (316) of first short blocking elements (318) adjacent to a second rectangular array (320) of second short blocking elements (322). The first blocking elements (318) and second blocking elements (322) and may form a thick partially blocking layer or a thin partially blocking layer, as described in reference to FIG. 1C and FIG. 1D. Ion implanted regions formed with the fourth partially blocking layer (314) may have a different dopant concentration under the first rectangular array (316) compared to a dopant concentration under the second rectangular array (320), which may be desirable for optimizing component performance.

FIG. 3E depicts a rectangular array of vertical long blocking elements (326) of a first material and horizontal long blocking elements (328) of a second material which form a fifth partially blocking layer (324). The vertical blocking elements (326) may block substantially all dopant atoms impacting them, or may block only a significant fraction, preferably between 25 and 75 percent. Similarly, the horizontal blocking elements (328) may block substantially all dopant atoms impacting them, or may block only a significant fraction, also preferably between 25 and 75 percent.

Partially blocking layers formed with other configurations of blocking elements are within the scope of the instant invention. For example, long linear blocking elements may be combined with short blocking elements to obtain a desired concentration of dopant atoms in an implanted region. In another example, a partially blocking layer may be formed of a combination of a first set of spatially blocking elements and a second set of spatially non-uniform blocking elements. In a further example, a solid partially blocking layer may be combined with a reticulated partially blocking layer to obtain a desired concentration of dopant atoms in an implanted region.

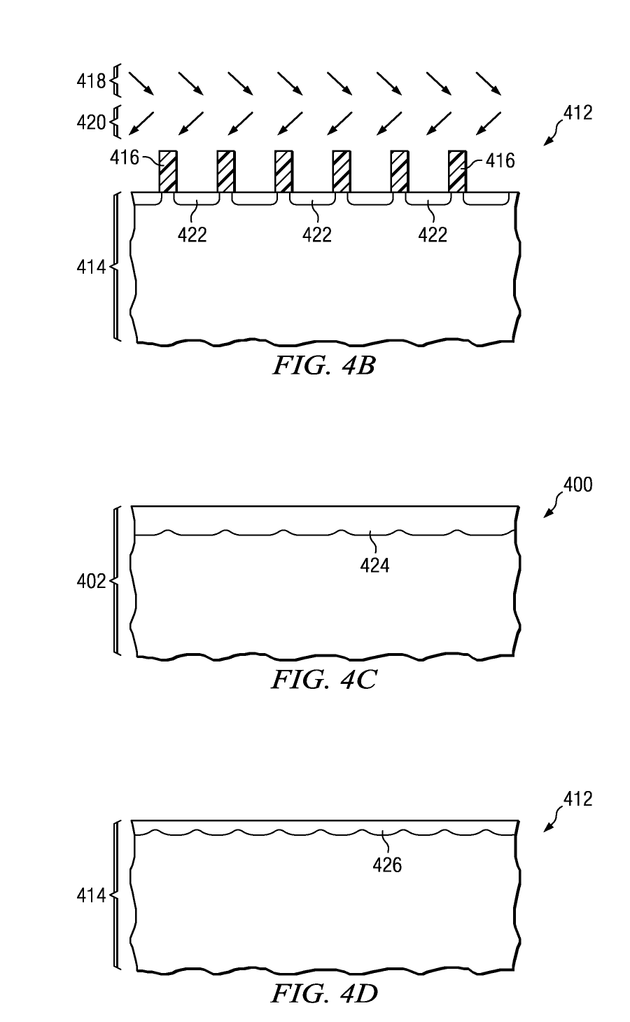

Embodiments of reticulated partially blocking layers may be combined with angled ion implantation processes to provide flexibility in concentrations of dopant atoms in various implanted regions among ICs fabricated in different substrates using a single photomask. Angled ion implantation processes typically implant dopant atoms in two or four subdoses in which each subdose is implanted at an angle with respect to an axis perpendicular to a top surface of a substrate being implanted. The implant directions for the subdoses are typically uniformly distributed around the perpendicular axis to provide a uniform concentration of dopant atoms adjacent to features protruding from the top surface of the substrate being implanted, such as transistor gates. Typical angles of angles ion implantation processes are between 2 and 30 degrees, although angle ion implants with lower angles and higher angles have been performed on occasion. The implantation angles of the subdoses may be varied for different substrates. FIG. 4A through FIG. 4D depict two ICs fabricated on different substrates with two different angled ion implantation processes through identical partially blocking layers. FIG. 4A depicts a first IC (400), which is formed in a first substrate (402). A first instance of a reticulated partially blocking layer (404) is formed on a top surface of the first substrate (402). A first angled ion implant process, in which a first subdose of dopant atoms (406) is implanted at a first angle with respect to a perpendicular axis to the top surface of the first substrate (402), and a second subdose of dopant atoms (408) is implanted at the first angle in an opposite direction is performed to produce a first implanted region (410). A fraction of the dopant atoms in the first and second subdoses (406, 408) which are blocked by the first instance of the reticulated partially blocking layer (404) depends on the first angle of the first angled ion implant process.

Doses of the first and second subdoses (406, 408) may be adjusted to obtain a desired dopant concentration in the first implanted region (410). Similarly, an implantation energy of the first and second subdoses (406, 408) may be adjusted to obtain a desired depth of the first implanted region (410).

FIG. 4B depicts a second IC (412), which is formed in a second substrate (414). A second instance of the reticulated partially blocking layer (416) is formed on a top surface of the second substrate (414). A second angled ion implant process, in which a third subdose of dopant atoms (418) is implanted at a second angle with respect to a perpendicular axis to the top surface of the second substrate (414), and a fourth subdose of dopant atoms (420) is implanted at the second angle in an opposite direction is performed to produce a second implanted region (422). A total amount of dopant atoms in the third and fourth subdoses (418, 420) is substantially equal to a total amount of dopant atoms in the first and second subdoses. The second angle is higher than the first angle, which results in a higher fraction of the dopant atoms in the third and fourth subdoses (418, 420) which are blocked by the second instance of the reticulated partially blocking layer (416) than the fraction of the dopant atoms in the first and second subdoses (406, 408) which were blocked by the first instance of the reticulated partially blocking layer (404).

Dose of the third and fourth subdoses (418, 420) may be adjusted to obtain a desired dopant concentration in the second implanted region (422). Similarly, an implantation energy of the third and fourth subdoses (418, 420) may be adjusted to obtain a desired depth of the second implanted region (422).

FIG. 4C depicts the first IC (400) after a first anneal operation activates and diffuses a portion of the first and second subdoses of dopant atoms in the first implanted region to form a first annealed region (424) in a top region of the first substrate (402).

FIG. 4D depicts the second IC (412) after a second anneal operation activates and diffuses a portion of the third and fourth subdoses of dopant atoms in the second implanted region to form a second annealed region (426) in a top region of the second substrate (414). Because a higher fraction of the dopant atoms in the third and fourth subdoses were blocked by the second instance of the reticulated partially blocking layer compared to the blocked fraction of dopant atoms in the first and second subdoses, a concentration of dopant atoms in the second annealed region (426) is less than a concentration of dopant atoms in the first annealed region.

Implanted areas in the first substrate and second substrate without partially blocking layers would receive full concentrations of the first and second subdoses and the third and fourth subdoses, respectively, resulting in substantially equivalent annealed regions.

Use of reticulated partially blocking layers with angled ion implants as described in reference to FIG. 4A through FIG. 4D is advantageous because it provides a capability for fabricating components in ICs in additional substrates with different properties without incurring a cost for additional photomasks.

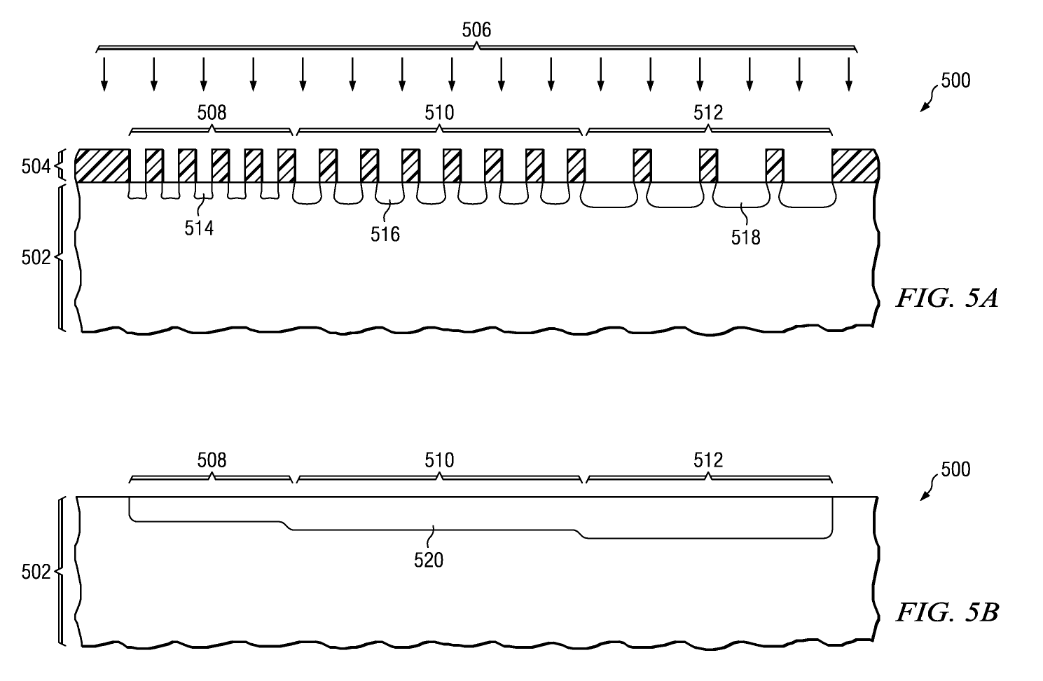

FIG. 5A and FIG. 5B illustrate a use of a reticulated partially blocking layer with areas of different transmission fractions to obtain a contiguous implanted region with a varying concentration of dopant atoms. Referring to FIG. 5A, an IC (500) is formed in a substrate (502). A reticulated partially blocking layer (504) is formed on a top surface of the substrate (502). A set of dopant atoms (506) is ion implanted through the partially blocking layer (504) into a top region of the substrate (502). The reticulated partially blocking layer (504) includes a first region (508) which blocks a first local fraction of the dopant atoms (506), a second region (510) which blocks a second local fraction, less than the first local fraction, of the dopant atoms (506), and a third region (512) which blocks a third local fraction, less than the second local fraction, of the dopant atoms (506). Dopant atoms (506) penetrating the first region (508) form a first implanted region (514) in a top region of the substrate (502). Similarly, dopant atoms (506) penetrating the second region (510) form a second implanted region (516) in a top region of the substrate (502), and dopant atoms (506) penetrating the third region (512) form a third implanted region (518) in a top region of the substrate (502).

A dose of the set of dopant atoms (506) may be adjusted to obtain a desired dopant concentration in either the first implanted region (514), the second implanted region (516) or the third implanted region (518). Similarly, an implantation energy of the set of dopant atoms (506) may be adjusted to obtain a desired depth in either the first implanted region (514), the second implanted region (516) or the third implanted region (518).

FIG. 5B depicts the IC (500) after an anneal operation which activates a portion of the dopant atoms in the first implanted region, the second implanted region and the third implanted region to form a continuous annealed region (520). A concentration of dopant atoms in the implanted region corresponding to the first region (508) is less than a concentration of dopant atoms in the implanted region corresponding to the second region (510), which is less than a concentration of dopant atoms in the implanted region corresponding to the third region (512). An ability to provide areas of an implanted region with different concentrations of dopant atoms is advantageous because component performance such as operating voltage may be improved without adding process cost or complexity.

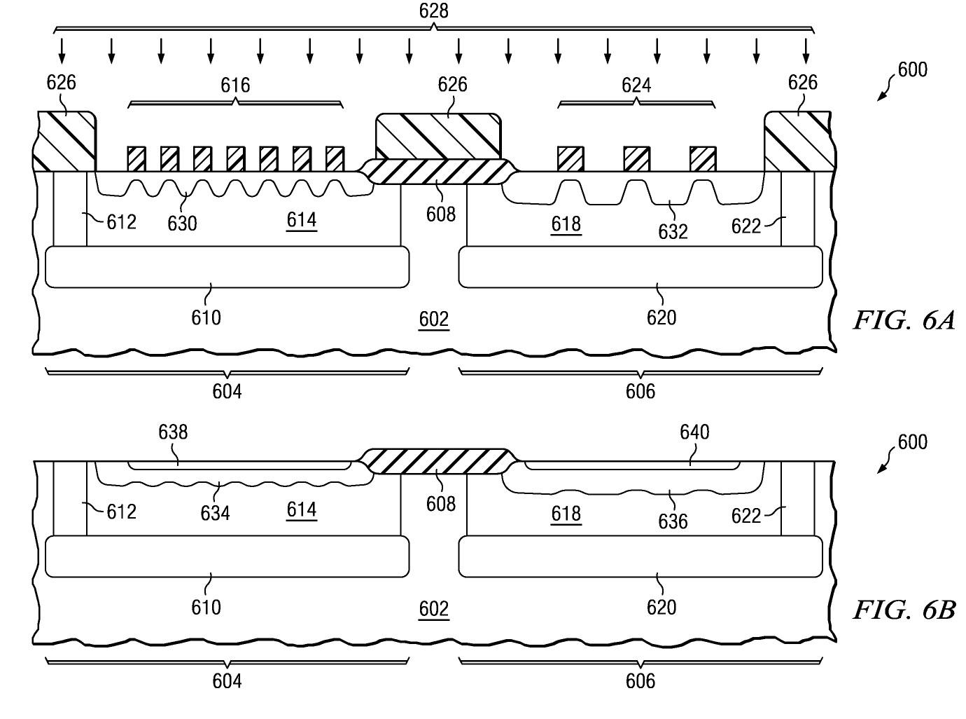

FIG. 6A and FIG. 6B are cross-sections of an IC with two embodiments of the instant invention to modify base regions of bipolar transistors. Referring to FIG. 6A, an IC (600) includes a substrate (602) which may be a single crystal wafer, an SOI wafer, or other structure configured for fabricating the IC (600). An area for a first bipolar transistor (604) and an area for a second bipolar transistor area (606) are defined in the substrate (602). Field oxide (608) separates the area for the first bipolar transistor (604) and the area for the second bipolar transistor area (606). The first bipolar transistor (604) includes a first deep n-well collector (614) and an optional first buried collector (610) and first sinker (612). A first partially blocking layer (616) is formed on a top surface of the substrate in the area for the first bipolar transistor (604). Similarly, the area for the second bipolar transistor (606) includes a second deep n-well collector (618) and an optional second buried collector (620) and second sinker (622). A second partially blocking layer (624) is formed on the top surface of the substrate in the area for the second bipolar transistor (606). A photoresist pattern (626) is formed on the top surface of the substrate (602) to block dopant atoms from areas outside the regions to be implanted. The first partially blocking layer (616) and the second partially blocking layer (624) may be formed from photoresist used to form the photoresist pattern (626) or may be formed form another material, as discussed in reference to FIG. 1B. In one realization of the instant embodiment, the first partially blocking layer (616) and the second partially blocking layer (624) may be formed concurrently. Dopant atoms (628) are ion implanted through the first partially blocking layer (616) and the second partially blocking layer (624) to form a first implanted base region (630) in the area for the first bipolar transistor (604) and a second implanted base region (632) in the area for the second bipolar transistor (606). The first partially blocking layer (616) reduces an average depth and concentration of dopant atoms (628) in the first implanted base region (630) compared to an implanted region with no partially blocking layer. This is advantageous because it provides a method of forming a bipolar transistor with a higher gain in the IC (600) without adding fabrication cost or complexity. The second partially blocking layer (624) reduces an average depth and concentration of dopant atoms (628) in the second implanted base region (632) compared to an implanted region with no partially blocking layer. Moreover, the average depth and concentration of dopant atoms (628) in the second implanted base region (632) may be different from the average depth and concentration of dopant atoms (628) in the first implanted base region (630). This is advantageous because it provides a method of forming bipolar transistors with different gains in the IC (600) without adding fabrication cost or complexity.

Blocking elements in the partially blocking layers (616, 624) disclosed above may be formed with varying lateral dimensions and spacing across the areas defined for the bipolar transistors (604, 406) to further enhance a parameter of interest, such as gain, breakdown voltage, or safe operating area. For example, a base width may be modified from base center to base termination in order to improve a tradeoff of current uniformity versus internal resistance or versus self-heating to avoid current filamentation at high current levels.

FIG. 6B depicts the IC (600) after an anneal operation which activates a portion of the dopant atoms in the first implanted base region and a portion of the dopant atoms in the second implanted base region to form a first annealed base region (634) in the area defined for the first bipolar transistor (604) and to form a second annealed base region (636) in the area defined for the second bipolar transistor (606). The first partially blocking layer and second partially blocking layer may optionally be removed prior to subsequent processing of the IC (600). A first emitter region (638) is formed in the area defined for the first bipolar transistor (604) in a top region of the substrate (602).

It will be recognized by those familiar with bipolar transistors in ICs that embodiments similar to those described in reference to FIG. 6A and FIG. 6B may be formed in reverse polarity by appropriate changes of dopant types.

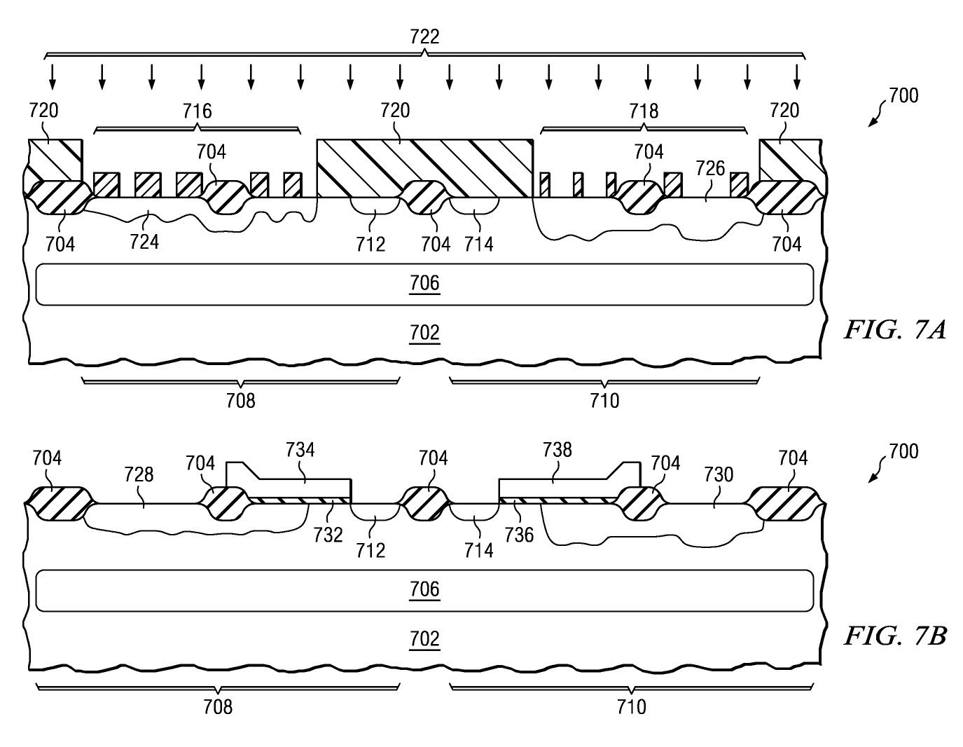

FIG. 7A and FIG. 7B are cross-sections of an IC with two embodiments of the instant invention to modify drain regions of DEMOS transistors. Referring to FIG. 7A, an IC (700) includes a substrate (702) which may be a single crystal wafer, an SOI wafer, or other structure configured for fabricating the IC (700). Field oxide (704) is formed at a top region of the substrate to isolate various components in the IC (700). An optional p-type buried layer (706) is formed in the substrate (702) under an area defined for a first DEMOS transistor (708) and an area defined for a second DEMOS transistor (710). The first DEMOS transistor (706) includes a first source diffused region (712). Similarly, the second DEMOS transistor includes a second source diffused region (714). A first partially blocking layer (716) is formed on a top surface of the substrate (702) in the area for the first DEMOS transistor (708). A second partially blocking layer (718) is formed on a top surface of the substrate (702) in the area for the second DEMOS transistor (710). A photoresist pattern (720) is formed on the top surface of the substrate (702) to block dopant atoms from areas outside the regions to be implanted. The first partially blocking layer (716) and the second partially blocking layer (718) may be formed from photoresist used to form the photoresist pattern (720) or may be formed form another material, as discussed in reference to FIG. 1B. In one realization of the instant embodiment, the first partially blocking layer (716) and the second partially blocking layer (718) may be formed concurrently. Dopant atoms (722) are ion implanted through the first partially blocking layer (716) and the second partially blocking layer (718) to form a first implanted drain region (724) in the area for the first DEMOS transistor (708) and a second implanted drain region (726) in the area for the second DEMOS transistor (710). The first partially blocking layer (716) reduces an average depth and concentration of dopant atoms (722) in the first implanted drain region (724) in a first drain depletion region and in a first drain contact region compared to an implanted region with no partially blocking layer. This is advantageous because it provides a method of forming a DEMOS transistor with a higher operating voltage and a higher breakdown potential with respect to the buried layer (706) in the IC (700) without adding fabrication cost or complexity. The second partially blocking layer (718) reduces an average depth and concentration of dopant atoms (722) in the second implanted drain region (726) in a second drain depletion region and in a second drain contact region compared to an implanted region with no partially blocking layer. Moreover, the average depth and concentration of dopant atoms (722) in the second implanted drain region (726) may be different from the average depth and concentration of dopant atoms (722) in the first implanted drain region (724). This is advantageous because it provides a method of forming DEMOS transistors with different operating voltages and different breakdown potentials in the IC (700) without adding fabrication cost or complexity.

Blocking elements in the partially blocking layers (716, 718) disclosed above may be formed with varying lateral dimensions and spacing across the areas defined for the bipolar transistors (708, 710) to further enhance a parameter of interest, such as operating voltage or breakdown potential with respect to the buried layer (706).

FIG. 7B depicts the IC (700) after an anneal operation which activates a portion of the dopant atoms in the first implanted drain region and a portion of the dopant atoms in the second implanted drain region to form a first annealed drain region (728) in the area defined for the first DEMOS transistor (708) and to form a second annealed drain region (730) in the area defined for the second DEMOS transistor (710). The first partially blocking layer and second partially blocking layer may optionally be removed prior to subsequent processing of the IC (700). A first gate dielectric layer (732) is formed on the top surface of the substrate (702) in the area defined for the first DEMOS transistor (708). A first DEMOS gate (734) is formed on a top surface of the first DEMOS gate dielectric layer (732). Similarly, a second gate dielectric layer (736) is formed on the top surface of the substrate (702) in the area defined for the second DEMOS transistor (710), and a second DEMOS gate (738) is formed on a top surface of the second DEMOS gate dielectric layer (736).

It will be recognized by those familiar with bipolar transistors in ICs that embodiments similar to those described in reference to FIG. 7A and FIG. 7B may be formed in reverse polarity by appropriate changes of dopant types.

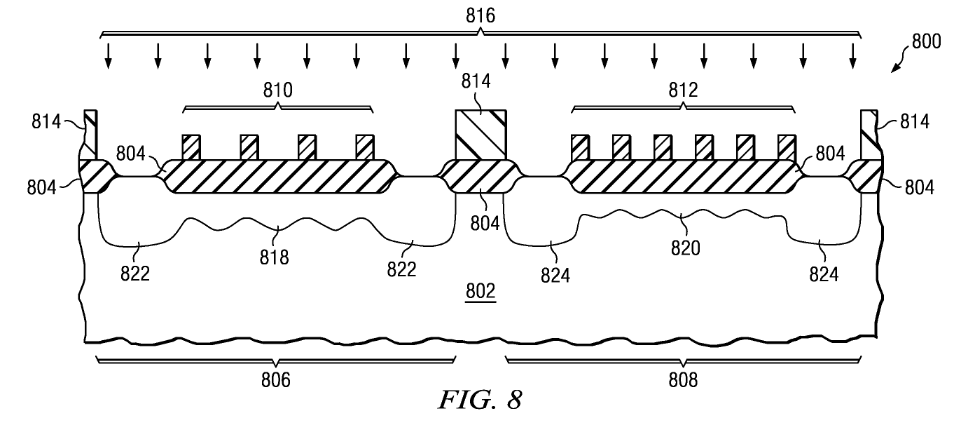

FIG. 8 is a cross-section of an IC with two implanted resistors formed according embodiments of the instant invention. An IC (800) includes a substrate (802) of a first conductive type which may be a single crystal wafer, an SOI wafer, or other structure configured for fabricating the IC (800). Field oxide (804) is formed in a top region of the substrate (802) to isolate components in the IC (800). An area for a first implanted resistor (806) and an area for a second implanted resistor (808) are defined in the substrate (802). Field oxide (804) is formed at a top region of the substrate to isolate various components in the IC (800). A first partially blocking layer (810) is formed on a top surface of the field oxide (804) in the area defined for the first implanted resistor (806). A second partially blocking layer (812) is formed on a top surface of the field oxide (804) in the area defined for the second implanted resistor (808). A photoresist pattern (814) is formed on a top surface of the IC (800) to block dopant atoms from areas outside the regions to be implanted. The first partially blocking layer (810) and the second partially blocking layer (812) may be formed from photoresist used to form the photoresist pattern (814) or may be formed form another material, as discussed in reference to FIG. 1B. In one realization of the instant embodiment, the first partially blocking layer (810) and the second partially blocking layer (812) may be formed concurrently. Dopant atoms (816) are ion implanted through the first partially blocking layer (810) and the second partially blocking layer (812) to form a first implanted resistor body region (818) in the area for the first implanted resistor (806) and a second implanted resistor body region (820) in the area for the second implanted resistor (808). A set of first implanted resistor head regions (822) is also formed in the area defined for the first implanted resistor (806) by the implanted dopant atoms (816). A set of second implanted resistor head regions (824) is also formed in the area defined for the second implanted resistor (808) by the implanted dopant atoms (816). The first partially blocking layer (810) reduces an average depth and concentration of dopant atoms (816) in the first implanted resistor body region (818) compared to an implanted resistor body region with no partially blocking layer. This is advantageous because it provides a method of forming an implanted resistor with a different sheet resistivity in the IC (700) without adding fabrication cost or complexity. The second partially blocking layer (812) reduces an average depth and concentration of dopant atoms (816) in the second implanted

The first partially blocking layer (810) and second partially blocking layer (812) may optionally be removed prior to subsequent processing of the IC (800). An anneal operation is performed on the IC (800) which activates a portion of the dopant atoms (816) in the first implanted resistor body region (818) and a portion of the dopants atoms (816) in the second implanted resistor body region (820), to form annealed resistor bodies in the first and second implanted resistors (806, 808). Sheet resistivities of the annealed resistor bodies reflect the difference in concentrations of dopant atoms corresponding to the differences between the first and second partially blocking layers (810, 812), which is advantageous because it provides a method of forming implanted resistors with different sheet resistivities in the IC (800) without adding fabrication cost or complexity.

Blocking elements in the partially blocking layers (810, 812) disclosed above may be formed with varying lateral dimensions and spacing across the areas defined for the first and second implanted resistors (806, 808) to vary a local sheet resistivity in order to reduce power dissipation in portions of the implanted resistors (806, 808). For example, the lateral dimensions and spacing of the blocking elements in the partially blocking layers (810, 812) may be varied to reduce the local sheet resistivity adjacent to the resistor heads (822, 824) in order to reduce a temperature increase in contacts, not shown in FIG. 8 for clarity, connected to the resistor heads (822, 824), and thereby reduce thermally dependent degradation mechanisms in the contacts.

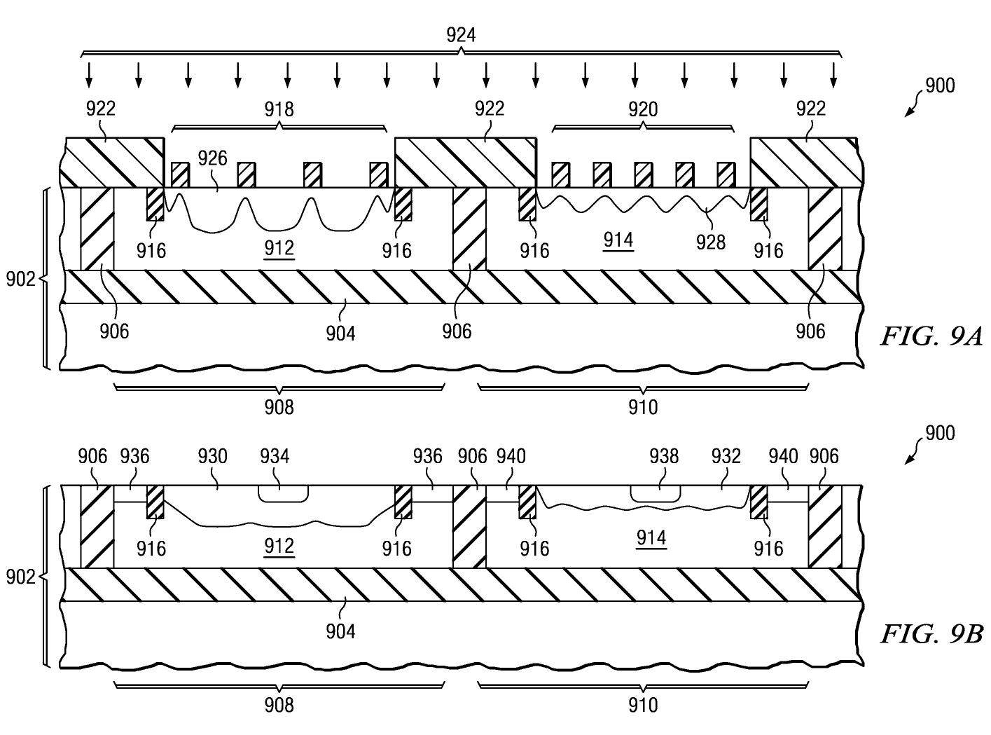

FIG. 9A and FIG. 9B are cross-sections of an IC with two junction field effect transistors (JFETs) formed according embodiments of the instant invention. An IC (900) includes a substrate (902) which may be a single crystal wafer, an SOI wafer as depicted in FIG. 9A and FIG. 9B, or other structure configured for fabricating the IC (900). A buried oxide layer (904) and deep trench isolation elements (906) isolate a region defined for a first JFET (908) and a region defined for a second JFET (910) from other components in the IC (900). A first deep n-well (912) is formed in the area defined for the first JFET (908), and a second deep n-well (914) is formed in the area defined for the second JFET (908). Field oxide (916) is formed in the first deep n-well (912) and the second deep n-well (914) to isolate drain, source and gate regions in the first JFET (908) and second JFET (910). A first partially blocking layer (918) is formed on a top surface of the substrate (902) in the area for the first JFET (908). A second partially blocking layer (920) is formed on a top surface of the substrate (902) in the area for the second JFET (910). A photoresist pattern (922) is formed on the top surface of the substrate (902) to block dopant atoms from areas outside the regions to be implanted. The first partially blocking layer (918) and the second partially blocking layer (920) may be formed from photoresist used to form the photoresist pattern (922) or may be formed form another material, as discussed in reference to FIG. 1B. In one realization of the instant embodiment, the first partially blocking layer (918) and the second partially blocking layer (920) may be formed concurrently. Dopant atoms (924) are ion implanted through the first partially blocking layer (918) and the second partially blocking layer (920) to form a first implanted gate region (926) in the area for the first JFET (908) and a second implanted gate region (928) in the area for the second JFET (910). The first partially blocking layer (918) reduces an average depth and concentration of dopant atoms (924) in the first implanted gate region (926) compared to an implanted region with no partially blocking layer. This is advantageous because it provides a method of forming a JFET with a higher threshold voltage in the IC (900) without adding fabrication cost or complexity. The second partially blocking layer (920) reduces an average depth and concentration of dopant atoms (924) in the second implanted gate region (928) compared to an implanted region with no partially blocking layer. Moreover, the average depth and concentration of dopant atoms (924) in the second implanted drain region (928) may be different from the average depth and concentration of dopant atoms (924) in the first implanted drain region (926). This is advantageous because it provides a method of forming JFETs with different threshold voltages in the IC (900) without adding fabrication cost or complexity.

Blocking elements in the partially blocking layers (918, 920) disclosed above may be formed with varying lateral dimensions and spacing across the areas defined for the JFETs (908, 910) to further enhance a parameter of interest, such as on-state current or pinch-off voltage.

FIG. 9B depicts the IC (900) after an anneal operation which activates a portion of the dopant atoms in the first implanted gate region and a portion of the dopant atoms in the second implanted gate region to form a first annealed gate region (930) in the area defined for the first JFET (908) and to form a second annealed gate region (932) in the area defined for the second JFET (910). The first partially blocking layer and second partially blocking layer may optionally be removed prior to subsequent processing of the IC (900). An optional first gate p-type diffused contact region (934) may be formed in the first annealed gate region (930). N-type first source and drain diffused contact regions (936) are formed at the top surface of the first deep n-well (912) flanking the first annealed gate region (930). Similarly, an optional second gate p-type diffused contact region (938) may be formed in the second annealed gate region (932). N-type second source and drain diffused contact regions (940) are formed at the top surface of the second deep n-well (914) flanking the second annealed gate region (932).

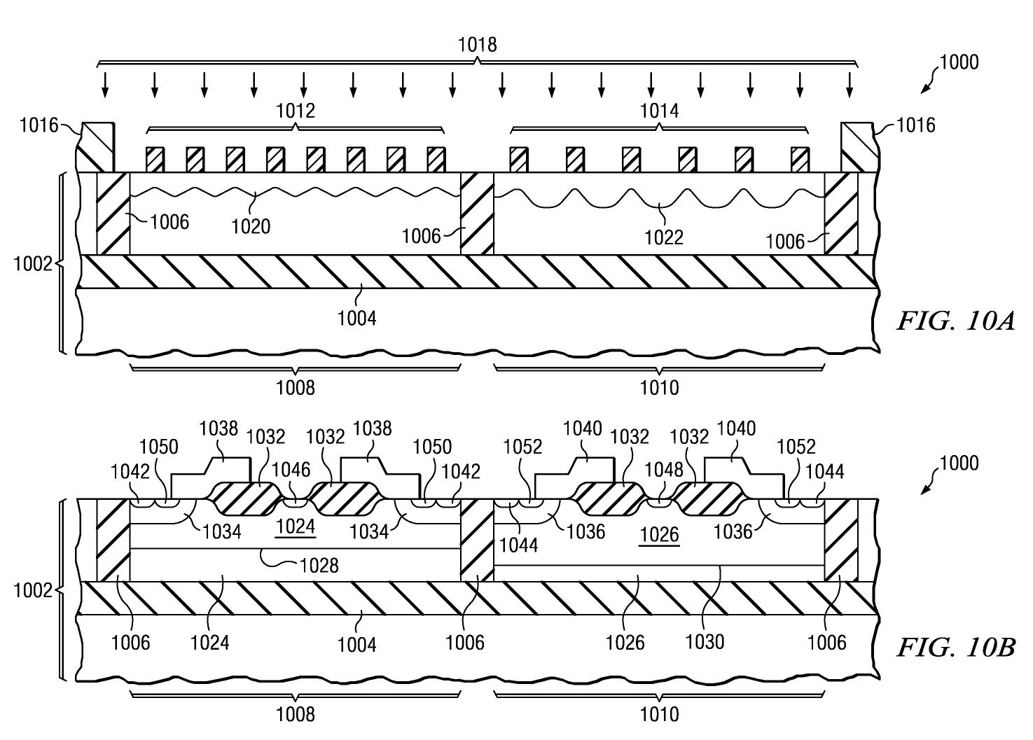

FIG. 10A and FIG. 10B are cross-sections of an IC with two lateral insulated gate bipolar transistors (L-IGBTs) formed according to embodiments of the instant invention. Referring to FIG. 10A, an IC (1000) includes a substrate (1002) which may be a single crystal wafer, an SOI wafer as depicted in FIG. 10A and FIG. 10B, or other structure configured for fabricating the IC (1000). A buried oxide layer (1004) and elements of deep trench isolation (1006) define an area in the substrate (1002) for a first L-IGBT (1008) and an area in the substrate (1002) for a second L-IGBT region (1010). A first partially blocking layer (1012) is formed on a top surface of the substrate (1002) in the area for the first L-IGBT (1008). A second partially blocking layer (1014) is formed on a top surface of the substrate (1002) in the area for the second L-IGBT (1010). A photoresist pattern (1016) is formed on the top surface of the substrate (1002) to block dopant atoms from areas outside the regions to be implanted. The first partially blocking layer (1012) and the second partially blocking layer (1014) may be formed from photoresist used to form the photoresist pattern (1016) or may be formed form another material, as discussed in reference to FIG. 1B. In one realization of the instant embodiment, the first partially blocking layer (1012) and the second partially blocking layer (1014) may be formed concurrently. Dopant atoms (1018) are ion implanted through the first partially blocking layer (1012) and the second partially blocking layer (1014) to form an n-type first implanted bipolar base region (1020) in the area for the first L-IGBT (1008) and an n-type second implanted bipolar base region (1022) in the area for the second L-IGBT (1010). The first partially blocking layer (1012) reduces an average depth and concentration of dopant atoms (1018) in the first implanted bipolar base region (1020) compared to an implanted region with no partially blocking layer. This is advantageous because it provides a method of forming an L-IGBT with a higher operating voltage in the IC (1000) without adding fabrication cost or complexity. The second partially blocking layer (1014) reduces an average depth and concentration of dopant atoms (1018) in the second implanted bipolar base region (1022) compared to an implanted region with no partially blocking layer. Moreover, the average depth and concentration of dopant atoms (1018) in the second implanted bipolar base region (1022) may be different from the average depth and concentration of dopant atoms (1018) in the first implanted bipolar base region (1020). This is advantageous because it provides a method of forming L-IGBTs with different operating voltages in the IC (1000) without adding fabrication cost or complexity.

Blocking elements in the partially blocking layers (1012, 1014) disclosed above may be formed with varying lateral dimensions and spacing across the areas defined for the L-IGBTs (1008, 1010) to further enhance a parameter of interest, such as on-state current.

Referring to FIG. 10B, fabrication of the first and second L-IGBTs (1008, 1010) continues with a base anneal process which diffuses and activates a portion of the dopant atoms in the first implanted bipolar base region throughout the area defined for the first L-IGBT (1008) above the buried oxide layer (1004) to form a first base diffused region (1024). Similarly, the base anneal process diffuses and activates a portion of the dopant atoms in the second implanted bipolar base region throughout the area defined for the second L-IGBT (1010) to form a second base diffused region (1026). An average concentration of dopant atoms in the first base diffused region (1024) is different from an average concentration of dopant atoms in the second base diffused region (1026), as depicted by the relative positions of a first equi-doping line (1028) in the first base diffused region (1024) along which a dopant atom concentration is, for example, 1·10¹⁶ and a second equi-doping line (1030) in the second base diffused region (1026) along which a dopant atom concentration is the same as along the first equi-doping line (1028).

Still referring to FIG. 10B, fabrication of the first and second L-IGBTs (1008, 1010) continues with formation of regions of field oxide (1032) at top surfaces of the first and second base diffused regions (1024, 1026). A p-type first source sink region (1034) is formed in the first base region (1024) and a p-type second source sink region (1036) is formed in the second base region (1026), typically by ion implanting dopants at a dose between 3·10¹² to 1·10¹⁵ cm⁻², and annealing the substrate (1002). In some embodiments, optional drain buffer regions, not shown in FIG. 10B for clarity, may be formed in the first and second base diffused regions (1024, 1026). A first gate dielectric layer, typically silicon dioxide, nitrogen doped silicon dioxide, silicon oxy-nitride, hafnium oxide, layers of silicon dioxide and silicon nitride, or other insulating material, is formed on the top surface of the first and second base diffused regions (1024, 1026). A first metal oxide semiconductor (MOS) gate structure (1038), typically polysilicon, is formed on a top surface of the gate dielectric layer over a boundary between the first base diffused region (1024) and the first source sink region (1034). Similarly, a second MOS gate structure (1040), also typically of polysilicon, is formed on the top surface of the gate dielectric layer over a boundary between the second base diffused region (1026) and the second source sink region (1036).

Continuing to refer to FIG. 10B, a p-type first source contact region (1042) is formed in the first source sink region (1034), and a p-type second source contact region (1044) is formed in the second source sink region (1036), typically by ion implantation of dopants with a dose of 3·10¹³ to 3·10¹⁶ cm⁻². A photoresist pattern to define regions for the first and second source contact regions (1038, 1340) is not shown in FIG. 10B for clarity. A p-type first drain region (1046) is formed at the top surface of the first diffused base region (1024) in a region separated from the first source sink region (1034) by field oxide (1032), and a p-type second drain region (1048) is formed at the top surface of the second diffused base region (1026) in a region separated from the second source sink region (1036) by field oxide (1032), typically by ion implantation of dopants with a dose of 3·10¹³ to 3·10¹⁶ cm⁻². A photoresist pattern to define regions for the first and second drain regions (1042, 1344) is not shown in FIG. 10B for clarity. It is common practice to form the first source contact region (1042), the second source contact region (1044), the first drain region (1046) and the second drain region (1048) with one ion implantation process. An n-type first MOS source region (1050) is formed in the first source sink region (1034) adjacent to the first MOS gate structure (1038), and an n-type second MOS source region (1052) is formed in the second source sink region (1036) adjacent to the second MOS gate structure (1040), typically by ion implantation of dopants at a dose of 3·10¹³ to 3·10¹⁶ cm⁻².

It is advantageous to have different average concentrations of dopants in the first and second diffused base regions (1024, 1226) because it provides L-IGBTs with different gains and/or blocking voltages in the IC (1000) without added fabrication cost or complexity.

It will be recognized by those familiar with L-IGBTs in ICs that embodiments similar to those described in reference to FIG. 10A and FIG. 10B may be formed in reverse polarity by appropriate changes of dopant types.

What is claimed is:

1. A method of ion implanting dopants into an integrated circuit, comprising the steps of:
forming a partially blocking layer in a first area of a top surface of said integrated circuit, such that said partially blocking layer does not extend over all of said top surface;
selecting an implantation energy of said dopants to obtain a desired depth of an implanted region below said partially blocking layer;
selecting a dose of said dopants to obtain a desired concentration of said dopants in said implanted region; and
ion implanting said dopants at said selected dose with said selected energy through said partially blocking layer, such that a fraction of said dopants are absorbed by said partially blocking layer, to form said implanted region.

2. The method of claim 1, in which said partially blocking layer is comprised of a continuous layer of uniform thickness.

3. The method of claim 1, in which said partially blocking layer is comprised of a reticulated absorbing structure which exposes a plurality of areas of said top surface of said integrated circuit.

4. The method of claim 3, in which said partially blocking layer further comprises
a first region comprising a plurality of said exposed areas, which absorbs a first local fraction of said dopants; and
a second region contiguous with said first region comprising a plurality of said exposed areas, which absorbs a second local fraction, substantially unequal to said first local fraction, of said dopants.

5. The method of claim 3, in which a portion of said dopants which impact said reticulated absorbing structure are transmitted through said reticulated absorbing structure into said implanted region.

6. The method of claim 1, further comprising the step of removing said partially blocking layer after said step of ion implanting said dopants is performed.

7. The method of claim 1, further comprising the step of forming a second partially blocking layer on a top surface of said first partially blocking layer.

8. The method of claim 1, further comprising the step of forming a second partially blocking layer on said top surface of said integrated circuit such that
said second partially blocking layer does not overlap said first partially blocking layer; and
said second partially blocking layer absorbs a second fraction of said dopants which is substantially unequal to said first fraction.

9. A method of forming an integrated circuit, comprising the steps of:
forming a partially blocking layer in a first area of a top surface of said integrated circuit, such that said partially blocking layer does not extend over all of said top surface;
selecting an implantation energy of said dopants to obtain a desired depth of an implanted region below said partially blocking layer;
selecting a dose of said dopants to obtain a desired concentration of said dopants in said implanted region; and
ion implanting said dopants at said selected dose with said selected energy through said partially blocking layer, such that a fraction of said dopants are absorbed by said partially blocking layer, to form said implanted region.

10. The method of claim 9, in which said partially blocking layer is comprised of a continuous layer of uniform thickness.

11. The method of claim 9, in which said partially blocking layer is comprised of a reticulated absorbing structure which exposes a plurality of areas of said top surface of said integrated circuit.

12. The method of claim 11, in which said partially blocking layer further comprises
a first region comprising a plurality of said exposed areas, which absorbs a first local fraction of said dopants; and
a second region contiguous with said first region, comprising a plurality of said exposed areas, which absorbs a second local fraction, substantially unequal to said first local fraction, of said dopants.

13. The method of claim 11, in which a portion of said dopants which impact said reticulated absorbing structure are transmitted through said reticulated absorbing structure into said implanted region.

14. The method of claim 9, further comprising the step of removing said partially blocking layer after said step of ion implanting said dopants is performed.

15. The method of claim 9, further comprising the step of forming a second partially blocking layer on a top surface of said first partially blocking layer.

16. The method of claim 9, further comprising the step of forming a second partially blocking layer on said top surface of said integrated circuit such that
said second partially blocking layer does not overlap said first partially blocking layer; and
said second partially blocking layer absorbs a second fraction of said dopants which is substantially unequal to said first fraction.

17. The method of claim 9, in which said implanted region is a base region of a bipolar transistor in said integrated circuit.

18. The method of claim 9, in which said implanted region is a drain region of a diffused drain metal oxide semiconductor transistor in said integrated circuit.
